(19) United States
(12) Patent Application Publication
(10) Pub. No.: US 2023/0066801 A1
(43) Pub. Date: Mar. 2, 2023

(54) ELECTRONIC DEVICE

(71) Applicants: Inventec (Pudong) Technology Corp., Shanghai (CN); Inventec Corporation, Taipei (TW)

(72) Inventors: Chun-Chi Lin, Taipei (TW); Szu-Yu Huang, Taipei (TW); I-Fang Chen, Taipei (TW); Ya-lan Kuo, Taipei (TW)

(73) Assignees: Inventec (Pudong) Technology Corp., Shanghai (CN); Inventec Corporation, Taipei (TW)

(21) Appl. No.: 17/901,835

(22) Filed: Sep. 1, 2022

(30) Foreign Application Priority Data
Sep. 2, 2021 (CN) 202111026437.9

(51) Int. Cl. H05K 7/20; G06F 1/20

(52) U.S. Cl. CPC H05K 7/20145; H05K 7/20154; G06F 1/203; H05K 1/0201

(57) ABSTRACT

An electronic device includes a base, a circuit board and a heat dissipating module. The base includes a bottom cover and a frame. The frame is disposed on the bottom cover. An accommodating space is between the bottom cover and the frame. The bottom cover has an air inlet. The circuit board is disposed in the accommodating space. The circuit board has a through hole. The through hole corresponds to the air inlet. The heat dissipating module is disposed in the accommodating space and located above the circuit board. The heat dissipating module includes a fan. The fan corresponds to the through hole. The fan drives airflow to flow into the accommodating space from the air inlet and the through hole along an axial direction of the fan and then flow out of the base from the accommodating space along the axial direction of the fan.

### BACKGROUND OF THE INVENTION

### 1. Field of the Invention

The invention relates to an electronic device and, more particularly, to an electronic device capable of effectively improving heat dissipating efficiency.

### 2. Description of the Prior Art

At present, a notebook computer has been considered a necessity by a lot of people in daily life. In general, the notebook computer is equipped with a heat dissipating module consisting of a fan and a heat dissipating fin set, so as to dissipate heat from electronic components in the notebook computer. In the conventional notebook computer, the fan drives airflow to flow into the notebook computer from a lower side and then flow out of the notebook computer from a rear side or a lateral side, such that a heat dissipating hole needs to be formed on the rear side or the lateral side of the notebook computer. Consequently, the appearance of the notebook computer is not concise. Furthermore, as the performance of electronic components improves, more and more heat is generated during the operation of the electronic components. In addition, since the notebook computer tends to be thin and light, more heat is generated by the electronic components and cannot be dissipated more efficiently. Therefore, the conventional design of heat dissipation can no longer meet the demand.

### SUMMARY OF THE INVENTION

The invention provides an electronic device capable of effectively improving heat dissipating efficiency, so as to solve the aforesaid problems.

According to an embodiment of the invention, an electronic device comprises a base, a circuit board and a heat dissipating module. The base comprises a bottom cover and a frame. The frame is disposed on the bottom cover. An accommodating space is between the bottom cover and the frame. The bottom cover has an air inlet. The circuit board is disposed in the accommodating space. The circuit board has a through hole. A position of the through hole corresponds to a position of the air inlet. The heat dissipating module is disposed in the accommodating space and located above the circuit board. The heat dissipating module comprises a fan. A position of the fan corresponds to the position of the through hole. The fan drives airflow to flow into the accommodating space from the air inlet and the through hole along an axial direction of the fan and then flow out of the base from the accommodating space along the axial direction of the fan.

As mentioned in the above, the fan drives airflow to flow into the accommodating space of the base from the air inlet of the bottom cover and the through hole of the circuit board along the axial direction of the fan and then flow out of the base from the accommodating space of the base along the axial direction of the fan. In other words, the fan of the invention drives the airflow to flow into the base from a lower side of the base and then flow out of the base from an upper side of the base along the axial direction of the fan. Since there is a completely open space above the heat dissipating module, the heat dissipating efficiency can be effectively improved. Furthermore, since the airflow in the invention flows out of the base from the upper side of the base, a heat dissipating hole does not need to be formed on a rear side or a lateral side of the base, such that the appearance of the electronic device can be more concise.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view illustrating an electronic device according to an embodiment of the invention.

FIG. 2 is a perspective view illustrating the electronic device shown in FIG. 1 from another viewing angle.

FIG. 3 is an exploded view illustrating the electronic device shown in FIG. 1.

FIG. 4 is a perspective view illustrating a heat dissipating module shown in FIG. 3 from another viewing angle.

FIG. 5 is a sectional view illustrating the electronic device shown in FIG. 1.

FIG. 6 is a top view illustrating the electronic device according to another embodiment of the invention.

FIG. 7 is a sectional view illustrating the electronic device shown in FIG. 6.

FIG. 8 is a top view illustrating the electronic device according to another embodiment of the invention.

### DETAILED DESCRIPTION

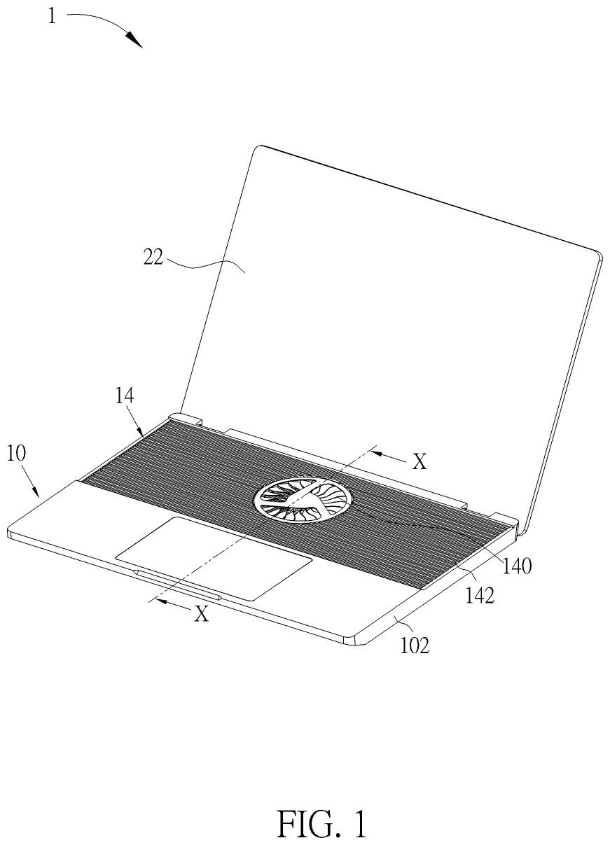

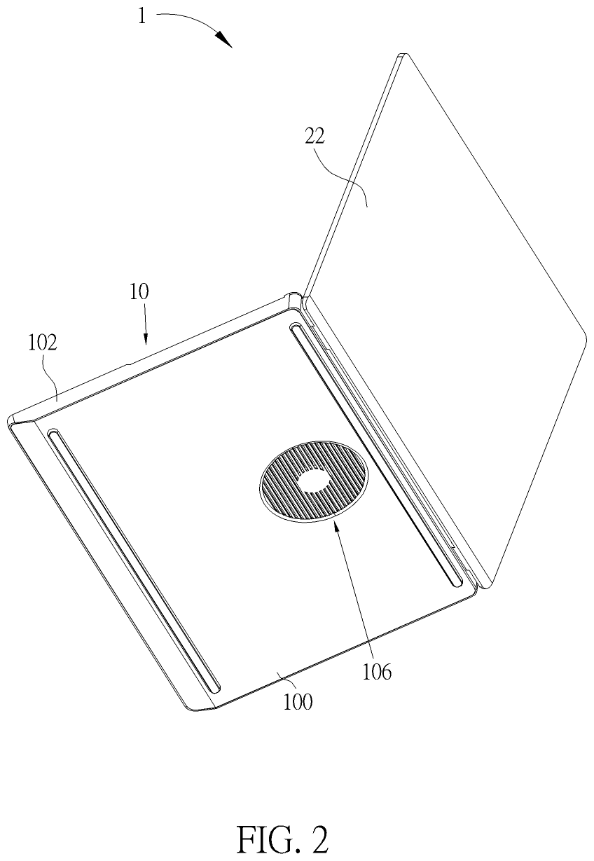

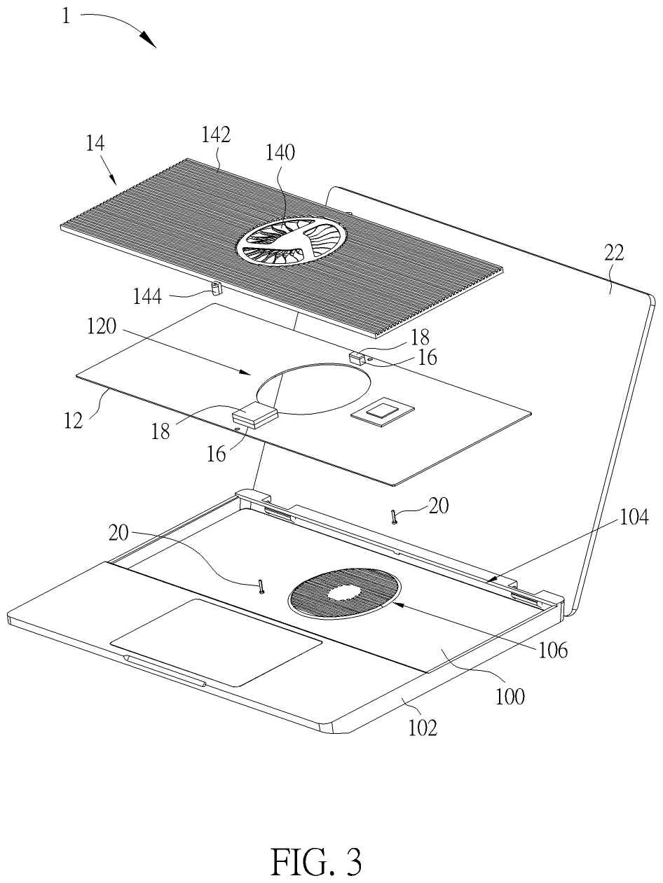

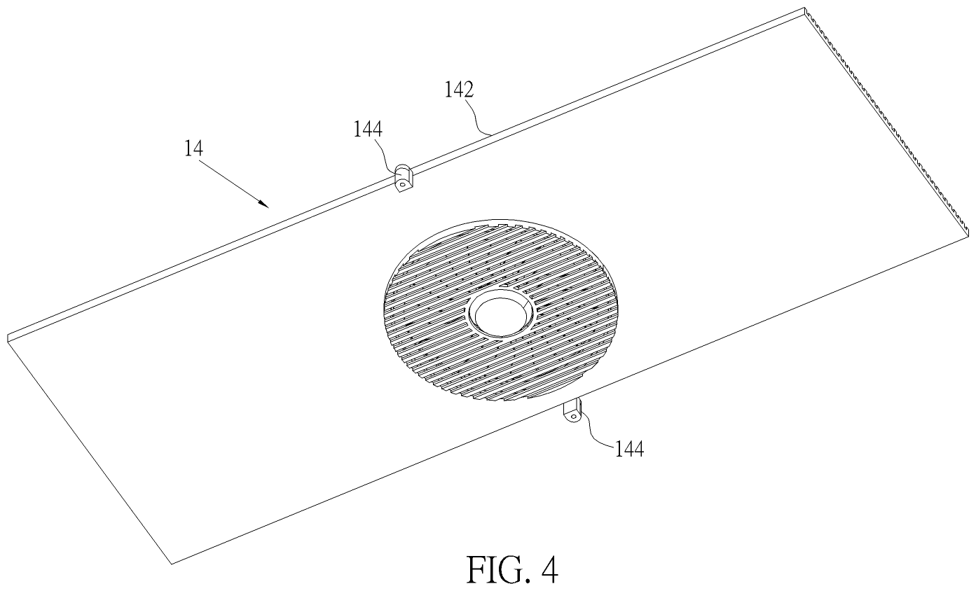

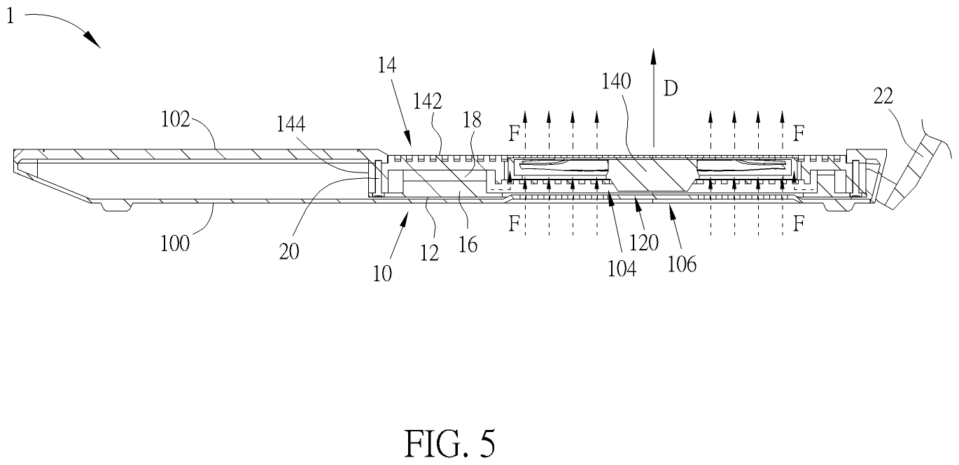

Referring to FIGS. 1 to 5, FIG. 1 is a perspective view illustrating an electronic device 1 according to an embodiment of the invention, FIG. 2 is a perspective view illustrating the electronic device 1 shown in FIG. 1 from another viewing angle, FIG. 3 is an exploded view illustrating the electronic device 1 shown in FIG. 1, FIG. 4 is a perspective view illustrating a heat dissipating module 14 shown in FIG. 3 from another viewing angle, and FIG. 5 is a sectional view illustrating the electronic device 1 shown in FIG. 1 along line X-X.

As shown in FIGS. 1 to 5, the electronic device 1 comprises a base 10, a circuit board 12, a heat dissipating module 14, an electronic component 16, a heat conducting medium 18, a plurality of fixing members 20 and a display device 22. In this embodiment, the display device is pivotally connected to the base 10, such that the electronic device 1 is served as, but is not limited to, a notebook computer. In another embodiment, the electronic device 1 may also be served as other electronic devices without the display device 22. In general, the electronic device 1 may be further equipped with some necessary hardware and/or software components for specific purposes, such as memory, power supply, applications, communication module, etc., and it depends on practical applications.

The base 10 comprises a bottom cover 100 and a frame 102. The frame 102 is disposed on the bottom cover 100, and an accommodating space 104 is between the bottom cover 100 and the frame 102. The bottom cover 100 has an air inlet 106. The circuit board 12 is disposed in the accommodating space 104 and the circuit board 12 has a through hole 120, wherein a position of the through hole 120 corresponding to a position of the air inlet 106. In this embodiment, there are two electronic components 16 disposed on the circuit board 12. It should be noted that the number of the electronic components 16 may be determined according to practical applications, so the invention is not limited to the embodiment shown in the figures. The electronic component 16 may be a central processing unit (CPU), a graphics processing unit (GPU), a solid-state drive (SSD) or other electronic components according to practical applications.

The heat dissipating module 14 is disposed in the accommodating space 104 and located above the circuit board 12. In this embodiment, the heat dissipating module 14 comprises a fan 140 and a heat dissipating fin set 142, wherein the fan 140 may be disposed at a middle position of the heat dissipating fin set 142. A position of the fan 140 corresponds to the position of the through hole 120 of the circuit board 12, and a position of the heat dissipating fin set 142 corresponds to positions of the electronic components 16. In this embodiment, there are two heat conducting mediums 18 respectively disposed on the two electronic components 16 and abutting against the heat dissipating fin set 142, such that heat generated by each electronic component 16 can be conducted to the heat dissipating fin set 142 through the heat conducting medium 18. Then, the heat is dissipated by the heat dissipating fin set 142 to the outside of the electronic device 1. The heat conducting medium 18 may be heat conducting glue or other heat conducting components according to practical applications.

In this embodiment, the heat dissipating fin set 142 may comprise a plurality of fixing pillars 144. To assemble the base 10, the fixing members 20 may pass through the circuit board 12 and the fixing pillars 144 to be fixed to the frame 102 first, such that the circuit board 12 and the heat dissipating module 14 are fixed to the frame 102 and the heat conducting mediums 18 on the electronic components 16 are tightly in contact with the heat dissipating fin set 142. Then, the bottom cover 100 is connected to the frame 100 to finish the assembly of the base 10. When the circuit board 12 and/or the heat dissipating module 14 needs to be maintained, a user only needs to detach the bottom cover 100 and the fixing members 20 in sequence, such that it is very convenient. In this embodiment, the number of the fixing members 20 and the fixing pillars 144 are two, but the invention is not so limited. The number of the fixing members 20 and the fixing pillars 144 may be determined according to practical applications.

As shown in FIG. 5, the fan 140 may drive airflow F to flow into the accommodating space 104 of the base 10 from the air inlet 106 of the bottom cover 100 and the through hole 120 of the circuit board 12 along an axial direction D of the fan 140. At this time, the airflow F will take away the heat generated by the electronic components 16 and flow out of the base 10 from the accommodating space 104 of the base 10 along the axial direction D of the fan 140. In other words, the fan 140 drives the airflow F to flow into the base 10 from a lower side of the base 10 and then flow out of the base 10 from an upper side of the base 10 along the axial direction D of the fan 140. Since there is a completely open space above the heat dissipating module 14, the heat dissipating efficiency can be effectively improved. Furthermore, since the airflow F in the invention flows out of the base 10 from the upper side of the base 10, a heat dissipating hole does not need to be formed on a rear side or a lateral side of the base 10, such that the appearance of the electronic device 1 can be more concise. Moreover, the heat generated by the electronic components 16 may be further conducted to the heat dissipating fin set 142 through the heat conducting mediums 18 and then the heat is dissipated by the heat dissipating fin set 142 to the outside of the electronic device 1. Accordingly, the heat dissipating efficiency may be further improved.

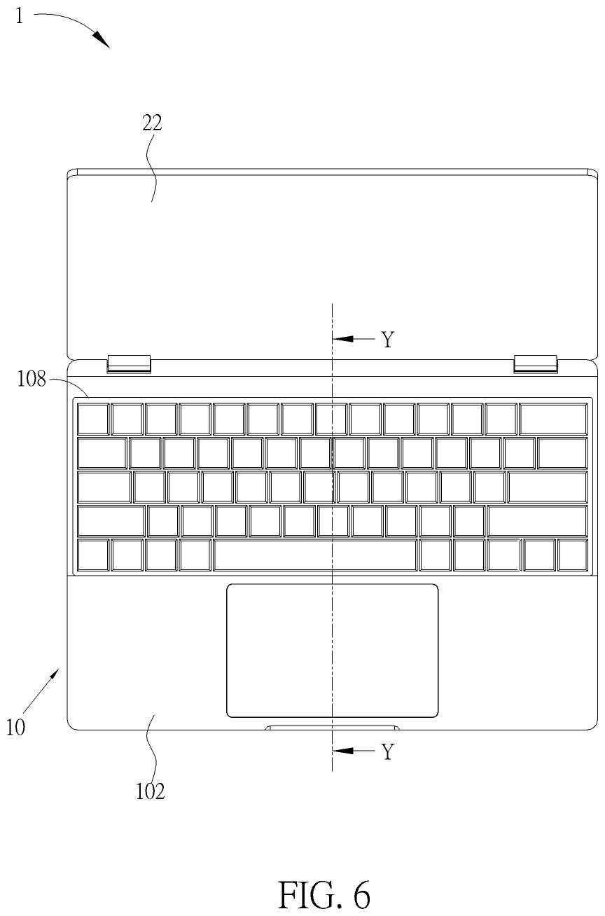

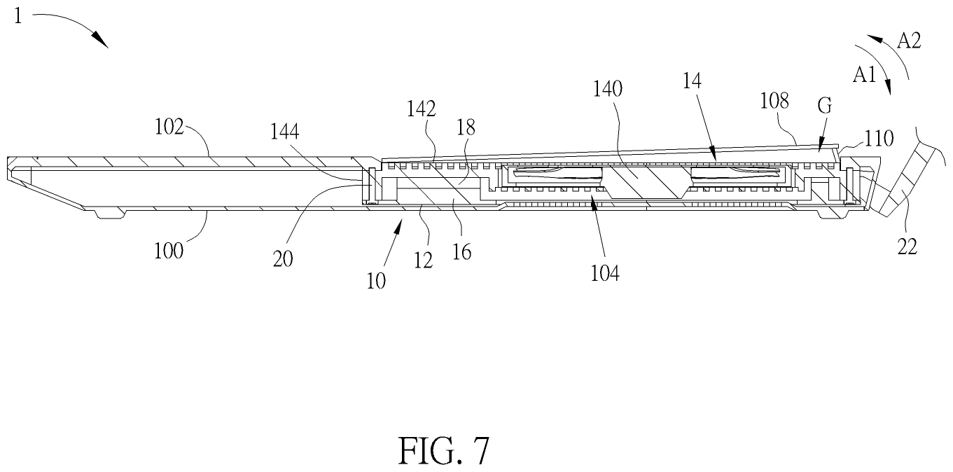

Referring to FIGS. 6 and 7, FIG. 6 is a top view illustrating the electronic device 1 according to another embodiment of the invention, and FIG. 7 is a sectional view illustrating the electronic device 1 shown in FIG. 6 along line Y-Y.

As shown in FIGS. 6 and 7, the base 10 may further comprise a keyboard 108 and a lift mechanism 110. In this embodiment, the keyboard 108 is movably disposed on the frame 102 and located above the accommodating space 104. The lift mechanism 110 is configured to drive the keyboard 108 to be lifted or closed with respect to the frame 102. As shown in FIG. 7, the lift mechanism 110 may drive the keyboard 108 to move in a direction of an arrow A1 to be lifted with respect to the frame 102 and drive the keyboard 108 to move in a direction of an arrow A2 to be closed with respect to the frame 102. When the keyboard 108 is lifted with respect to the frame 102, a gap G is formed between the keyboard 108 and the heat dissipating module 14. At this time, the heat dissipating module 14 is able to dissipate heat to the outside of the electronic device 1 through the gap G, so as to prevent the temperature of the keyboard 108 from getting too high. Furthermore, when the keyboard 108 is closed with respect to the frame 102, the keyboard 108 will shield the heat dissipating module 14. In another embodiment, the keyboard 108 may also be driven to move forward and backward with respect to the frame 102 by other mechanisms according to practical applications.

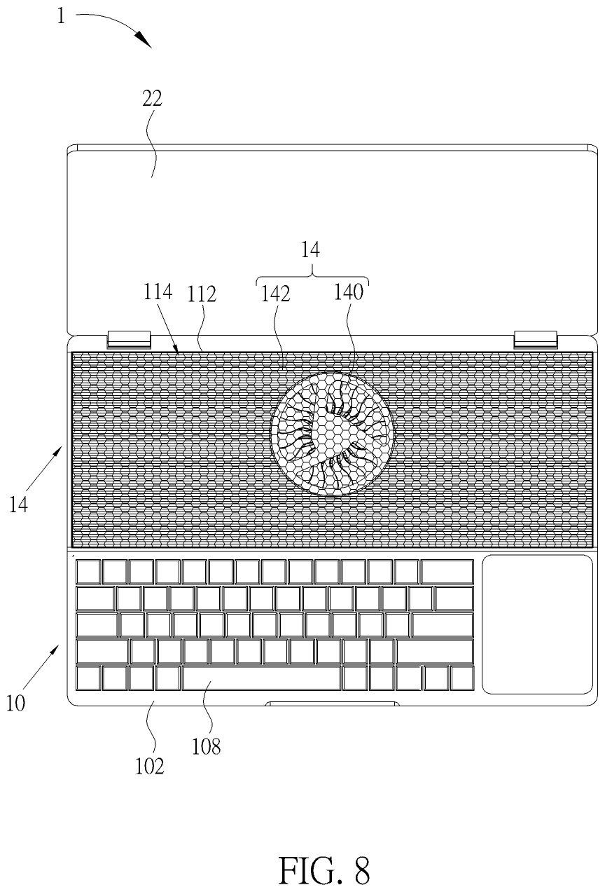

Referring to FIG. 8, FIG. 8 is a top view illustrating the electronic device 1 according to another embodiment of the invention.

As shown in FIG. 8, the base 10 may further comprise a keyboard 108 and a cover plate 112. In this embodiment, the keyboard 108 is disposed on the frame 102 and staggered with the heat dissipating module 14. The cover plate 112 is disposed on the frame 102 and adjacent to the keyboard 108. The cover plate 112 is configured to shield the heat dissipating module 14 to prevent a user from touching the heat dissipating module 14. In addition, the cover plate 112 has a plurality of air holes 114, such that the heat dissipating module 14 may dissipate heat to the outside of the electronic device 1 through the air holes 114.

As mentioned in the above, the fan drives airflow to flow into the accommodating space of the base from the air inlet of the bottom cover and the through hole of the circuit board along the axial direction of the fan and then flow out of the base from the accommodating space of the base along the axial direction of the fan. In other words, the fan of the invention drives the airflow to flow into the base from a lower side of the base and then flow out of the base from an upper side of the base along the axial direction of the fan. Since there is a completely open space above the heat dissipating module, the heat dissipating efficiency can be effectively improved. Furthermore, since the airflow in the invention flows out of the base from the upper side of the base, a heat dissipating hole does not need to be formed on a rear side or a lateral side of the base, such that the appearance of the electronic device can be more concise. In an embodiment, when the keyboard is located above the accommodating space of the base, the invention may use the lift mechanism to drive the keyboard to be lifted with respect to the frame, so as to form the gap between the keyboard and the heat dissipating module for heat dissipation. In another embodiment, when the keyboard is staggered with the heat dissipating module, the invention may use the cover plate to shield the heat dissipating module, so as to prevent the user from touching the heat dissipating module.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic device comprising:
a base comprising a bottom cover and a frame, the frame being disposed on the bottom cover, an accommodating space being between the bottom cover and the frame, the bottom cover having an air inlet;
a circuit board disposed in the accommodating space, the circuit board having a through hole, a position of the through hole corresponding to a position of the air inlet; and
a heat dissipating module disposed in the accommodating space and located above the circuit board, the heat dissipating module comprising a fan, a position of the fan corresponding to the position of the through hole;
wherein the fan drives airflow to flow into the accommodating space from the air inlet and the through hole along an axial direction of the fan and then flow out of the base from the accommodating space along the axial direction of the fan.

2. The electronic device of claim 1, further comprising an electronic component disposed on the circuit board, the heat dissipating module further comprising a heat dissipating fin set, a position of the heat dissipating fin set corresponding to a position of the electronic component.

3. The electronic device of claim 2, further comprising a heat conducting medium disposed on the electronic component and abutting against the heat dissipating fin set.

4. The electronic device of claim 2, further comprising a plurality of fixing members, the heat dissipating fin set comprising a plurality of fixing pillars, the fixing members passing through the circuit board and the fixing pillars to be fixed to the frame.

5. The electronic device of claim 1, wherein the base further comprises a keyboard movably disposed on the frame and located above the accommodating space; when the keyboard is closed with respect to the frame, the keyboard shields the heat dissipating module; when the keyboard is lifted with respect to the frame, a gap is formed between the keyboard and the heat dissipating module.

6. The electronic device of claim 5, wherein the base further comprises a lift mechanism configured to drive the keyboard to be lifted or closed with respect to the frame.

7. The electronic device of claim 1, wherein the base further comprises a keyboard disposed on the frame and staggered with the heat dissipating module.

8. The electronic device of claim 7, wherein the base further comprises a cover plate disposed on the frame and adjacent to the keyboard, the cover plate shields the heat dissipating module, and the cover plate has a plurality of air holes.

9. The electronic device of claim 1, further comprising a display device pivotally connected to the base.
